(19) United States
(12) Patent Application Publication
(10) Pub. No.: US 2018/0233492 A1
(43) Pub. Date: Aug. 16, 2018

(54) TRIANGULAR-COMBINATION LED CIRCUIT BOARD, TRIANGULAR LED DEVICE AND DISPLAY

(71) Applicant: FOSHAN NATIONSTAR OPTOELECTRONICS CO., LTD, Foshan City (CN)

(72) Inventors: Chuanbiao Liu, Foshan City (CN); Xiaofeng Liu, Foshan City (CN); Feng Gu, Foshan City (CN); Kuai Qin, Foshan City (CN); Yuanbin Lin, Foshan City (CN)

(73) Assignee: FOSHAN NATIONSTAR OPTOELECTRONICS CO., LTD, Foshan City (CN)

(21) Appl. No.: 15/729,119

(22) Filed: Oct. 10, 2017

(30) Foreign Application Priority Data
Feb. 15, 2017 (CN) 201710081218.8

(51) Int. Cl. H01L 25/075; H01L 33/62

(52) U.S. Cl. CPC H01L 25/0753; H01L 2933/0033; H01L 33/62

(57) ABSTRACT

A triangular-combination LED circuit board, comprising a plurality of triangular LED units, wherein vertexes of every six of the LED units are superimposed to jointly form a hexagonal central point such that every six of the LED units form a hexagonal LED array; the LED unit includes a substrate and pads disposed on the substrate; the pads include die bond pads; and three die bond pads are provided, respectively disposed at three vertexes of the triangular LED units. In the present invention, triangular LED units are set to form triangular LED devices which can be more densely arrayed on a PCB, so an LED display with LED devices arrayed at a smaller distance is generated, and pixel definition is strengthened. Meanwhile, in an LED circuit board, the LED units are closely arranged in a hexagonal shape, so the utilization rate of materials can be enhanced; moreover, a plurality of LED units can be bored at one time at the central point of the hexagon, and finally the LED devices can be quickly obtained by simple cutting, thus effectively enhancing the processing efficiency and reducing production cost.

### CROSS-REFERENCE TO RELATED APPLICATIONS

This application claims priority to Chinese Application No. CN 201710081218.8 having a filing date of Feb. 15, 2017, the entire contents of which are hereby incorporated by reference.

### FIELD OF TECHNOLOGY

The present invention relates to light-emitting devices, circuit boards, and displays, in particular to an LED circuit board, an LED device, and a display.

### BACKGROUND

Refer to FIG. 1, which is a schematic view of an LED display in the prior art. The LED display consists of a plurality of chip-type LED devices 01; each one of the LED devices 01 is provided with three LED chips 05; and the dot-to-dot interval between the LED devices 01 is D. In terms of light emission, the LED display mainly presents dot light emission, and the pixel definition of the display is mainly affected by the dot-to-dot interval D. Along with the continuous development of LED display technologies, higher requirements are imposed on displays with a large density and a small interval, and more and more attention is being drawn to the definition and the light-emitting consistency. In terms of the light emission, the LED display mainly presents dot light emission, and the pixel definition of the display is mainly affected by the dot-to-dot interval D. If the dot-to-dot interval is too large, the definition is relatively low. In case the total area of the LED display is limited (limited by the service sites, etc.), how to narrow the dot-to-dot interval D of the LED device becomes a key technical issue. Besides, the display attached to the LED devices presents dot light emission; the emitted light is inconsistent, and the light is not homogeneously mixed, so the display effect is affected.

### SUMMARY

In order to solve the above technical problems, the present invention provides an LED circuit board, an LED device and an LED display, which have a small dot-to-dot interval and a high pixel definition.

The technical solution of the present invention is as follows:

A triangular-combination LED circuit board, comprising a plurality of triangular LED units, wherein vertexes of every six of the LED units are superimposed to jointly form a hexagonal central point such that every six of the LED units form a hexagonal LED array; the LED unit includes a substrate and pads disposed on the substrate; the pads include die bond pads; and three die bond pads are provided, respectively disposed at three vertexes of the triangular LED units.

Further, the LED unit is regular-triangle-shaped.

Further, the pads also comprise a common pad; the substrate is formed with a plurality of through-holes; the through-holes are respectively disposed at triangular vertexes of the LED units and on the common pad; pins are disposed on back of the substrate, and the pins are disposed corresponding to the through-holes.

Further, the triangular-combination LED circuit board also comprises LED chips, wire solders and encapsulating glue; the LED chips are respectively fixed on the die bond pads; the wire solders respectively electrically connect the LED chips and the pads; and the encapsulating glue covers the substrate to encapsulate the LED chips and the wire solders.

A triangular LED device, obtained by cutting the aforementioned triangular-combination LED circuit board, is characterized by including a substrate, pads and LED chips; the substrate is triangular-shaped; the pads include three die bond pads which are respectively disposed at three vertexes of the substrate, and the LED chips are respectively fixed on the die bond pads.

Further, the triangular LED device also comprises wire solders and encapsulating glue; the wire solders respectively electrically connect the LED chips and the pads; and the encapsulating glue covers the substrate to encapsulate the LED chips and the wire solders.

Further, the pads also comprise a common pad; the substrate is formed with a plurality of through-holes; the through-holes are respectively disposed at three vertexes of the substrate and on the common pad; pins are disposed on back of the substrate, and the pins are disposed corresponding to the through-holes.

Further, the LED chips include a red LED chip, a blue LED chip and a green LED chip.

An LED display, comprising a plurality of LED devices; horizontally adjacent LED devices are arrayed upward and downward in an alternative way at an equal interval, and the LED devices are triangular LED devices as described in any one of the above relevant paragraphs.

Further, each one of the LED devices includes three LED chips, namely a red LED chip, a green LED chip and a blue LED chip; and the LED chips of every two or three adjacent LED devices can form an RGB triangular dot matrix which comprises a red LED chip, a blue LED chip and a green LED chip.

In the present invention, triangular LED units are set to form triangular LED devices which can be more densely arrayed on a PCB, so an LED display with LED devices arrayed at a smaller distance is generated, and pixel definition is strengthened. Meanwhile, in an LED circuit board, the LED units are closely arranged in a hexagonal shape, so the utilization rate of materials can be enhanced; moreover, a plurality of LED units can be bored at one time at the central point of the hexagon, and finally the LED devices can be quickly obtained by simple cutting, thus effectively enhancing the processing efficiency and reducing production cost. Further, the LED chips are RGB chips, and the LED devices are arrayed on the LED display in a specific manner. In this way, adjacent LED devices can achieve a light mixing effect. The whole LED display presents surface light emission, so the emergent light of the display module is softer.

For better understanding and implementation, the present invention is described in detail below in conjunction with the attached drawings.

### BRIEF DESCRIPTION OF THE DRAWINGS

FIG. 1 is a schematic view of an LED display in the prior art;

FIG. 2A, FIG. 2B and FIG. 2C are schematic views of an LED circuit board of the present invention, wherein FIG. 2A is a front view of the LED circuit board without LED chips, wire solders and encapsulating glue; FIG. 2B is a front view of the LED circuit board with the LED chips, the wire solders and the encapsulating glue fixed; and FIG. 2C is a rear view of the LED circuit;

FIG. 3A and FIG. 3B are schematic views of an LED device of the present invention, wherein FIG. 3A is a front view and FIG. 3B is a rear view;

FIG. 4A and FIG. 4B are schematic views of an LED display (embodiment 1) of the present invention, wherein FIG. 4A is a front view, and FIG. 4B is a schematic view of an LED display compared with the prior art as shown in FIG. 1;

FIGS. 5A-F shows array modes of an RGB triangular dot matrix of the LED display (embodiment 1) of the present invention, wherein FIGS. 5A-F show six different optional array modes;

FIG. 6 shows another array mode of an RGB triangular dot matrix of an LED display (embodiment 2) of the present invention.

### DETAILED DESCRIPTION

The present invention provides a triangular-combination LED circuit board. The LED circuit board is provided with a plurality of triangular LED units. The LED circuit board can be cut according to the LED units; each one of the cut LED units forms a triangular LED device; and an LED display can be obtained by arraying a plurality of the triangular LED devices at an equal interval.

LED Circuit Board

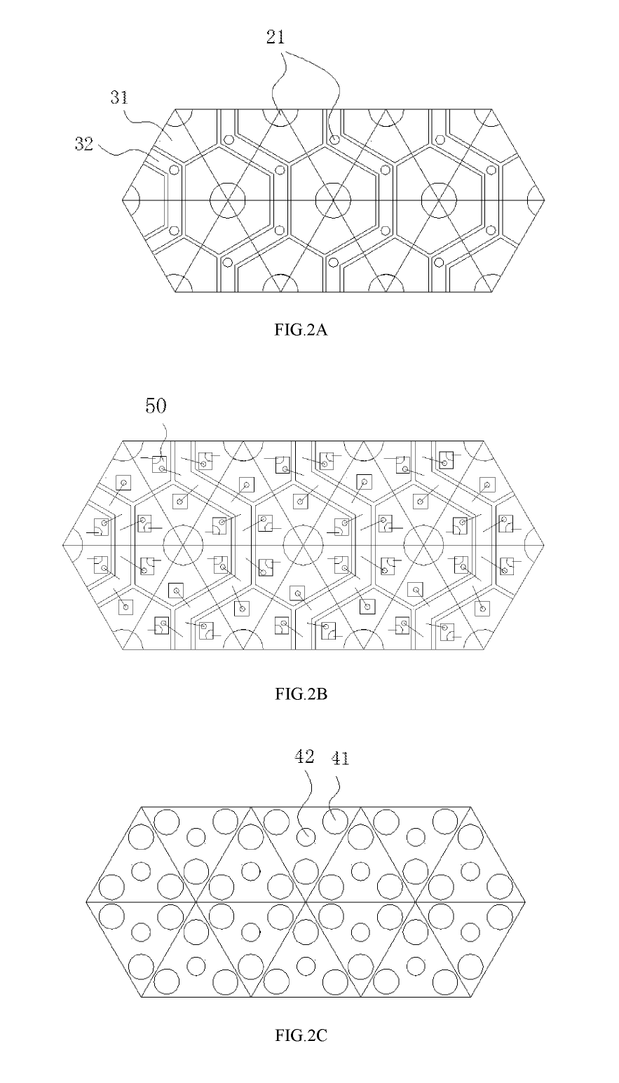

Refer to FIG. 2A, FIG. 2B and FIG. 2C, which are schematic view of an LED circuit board of the present invention. The LED circuit board includes a plurality of triangular LED units; the vertexes of every six of the LED units are superimposed to jointly form a hexagonal central point, so every six of the LED units form a hexagonal LED array. Preferably, the shapes of the LED units are regular triangles, and the vertexes of six LED units in a regular triangle shape are superimposed such that every six of the LED units in a regular triangle shape form an orthohexagonal LED array. A plurality of orthohexagonal LED arrays can extend on the plane of the LED circuit board along any direction, and the number thereof can be determined according to the number of the LED devices to be produced. FIG. 2A, FIG. 2B and FIG. 2C are only partial views of the LED circuit board. The LED circuit board is an intermediate product during the processing of the LED device, having LED units thereon that can form the LED devices. However, the shape of the LED circuit board may not be the shape of a single hexagon or the shape obtained by flatly arranging a plurality of hexagons. The LED circuit board may be a rectangular panel to facilitate processing. The hexagonal arrangement mode of the LED array is an arrangement mode with the largest density, can effectively enhance the utilization rate of materials, and ensure that the LED circuit board can be cut into triangular LED devices at one time, thus reducing procedures.

Each one of the LED units on the LED circuit board includes a substrate, pads, pins, LED chips 50, wire solders and encapsulating glue. Refer to FIG. 2A, FIG. 2B and FIG. 2C, wherein FIG. 2A is a front view of the LED circuit board without the LED chips, wire solders and encapsulating glue; FIG. 2B is a front view of the LED circuit board with the LED chips 50, the wire solders and the encapsulating glue fixed; and FIG. 2C is a rear view of the LED circuit.

The substrate is an insulating panel, specifically made of insulating materials such as plastics. The pads are metal pads, disposed on the substrate, including three die bond pads 31 and a common pad 32, wherein the pads are mutually spaced by an insulating channel such that the pads are electrically insulated. The substrate is formed with a conductive hole 21 corresponding to each one of the pads, and conductive materials are disposed in the conductive holes 21 or disposed on the inner walls of the conductive holes 21, for example the inner walls of the conductive holes are electroplated with copper. In this way, the pads can electrically communicate with the back of the substrate through the conductive holes. Four pins are disposed on the back of the substrate. The pins are metal pins, including three chip pins 41 and a common pin 42; the pins are mutually electrically insulated, and are disposed corresponding to the positions of the conductive holes 21. In this way, each one of the pads can electrically communicate with each corresponding one of the pins. The three die bond pads 31 are respectively disposed near the three vertexes of each one of the triangular LED units, and cover the vertexes. The conductive holes corresponding to the die bond pads 31 are disposed at the three vertexes, namely the central point of an hexagonal LED array. Therefore, holes only need be bored once at the central point of the hexagon. Each one of the die bond pads 31 is electrically connected with three chip pins 41 on the back of the substrate through the corresponding one of the conductive holes. The common pad 32 is positioned approximately in the middle of each one of the LED units, generating an adjacency relationship with each one of the die bond pads 31 to facilitate the later wire soldering. The substrate is also formed with a conductive hole corresponding to the common pad 32, and the conductive hole communicates with the common pin on the back of the substrate. In this way, the common pad 32 electrically communicates with the common pin 42.

Each one of the LED units is provided with three LED chips 50, and each one of the LED chips 50 is fixed on each corresponding one of the die bond pads 31. Preferably, the three LED chips include a red LED chip, a blue LED chip and a green LED chip. Further, the red LED chip is a chip with a vertical structure, and both the green LED chip and the blue LED chip are chips with a horizontal structure. An electrode of the red LED chip is directly electrically connected with the die bond pads 31, and the other electrode is electrically connected with the common pad 32 through a wire solder. The two electrodes of each one of the blue LED chip and the green LED chip are respectively electrically connected with the die bond pads 31 and the common pad 32 through wire solders. The encapsulating glue is poured to uniformly cover the substrate, thus encapsulating the LED chips 50, the wire solders and the pads in a sealed way. The encapsulating glue may be transparent or matte epoxy resin or silicone resin.

In other embodiments, the shapes of the LED units and the LED devices may be other triangles instead of regular triangles, and the formed hexagonal LED arrays may be non-regular hexagonal. It is allowed that the position of the common pad 32 is not in the middle portion of the LED unit. The common pad can be divided into two or three wire solder pads; each one of the wire solder pads can be electrically connected with one or two LED chips, and the through-holes and pins corresponding to each one of the pads are also correspondingly altered. The LED chips on each one of the LED units may be LED chips in other colors or any combination of the RGB chips instead of the RGB chips.

LED Device

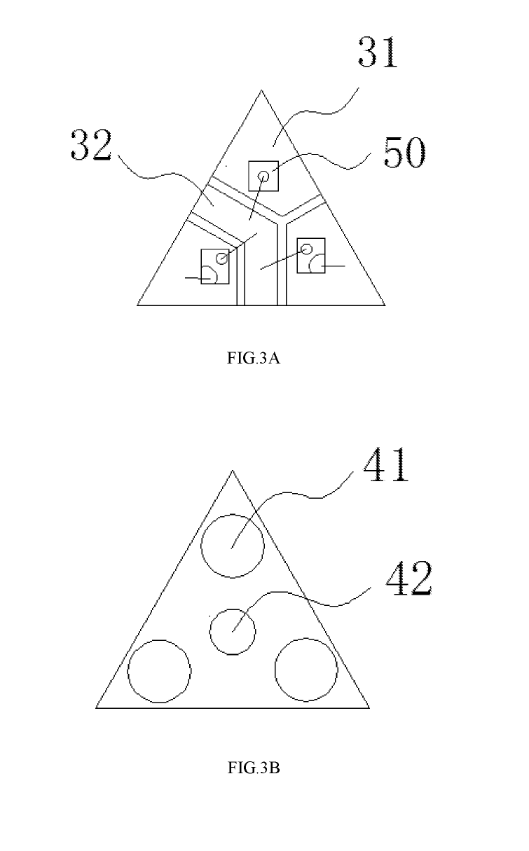

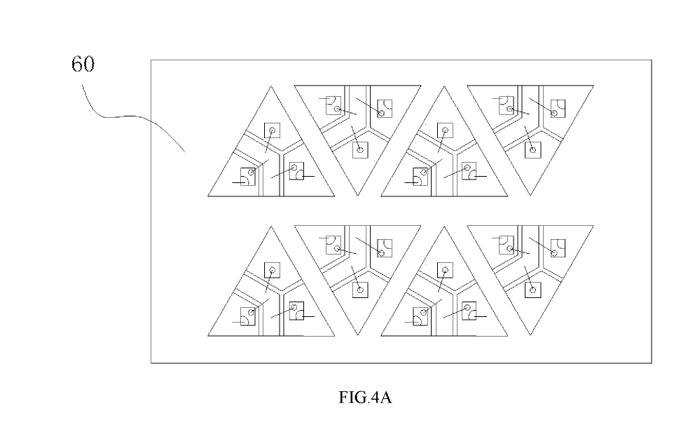

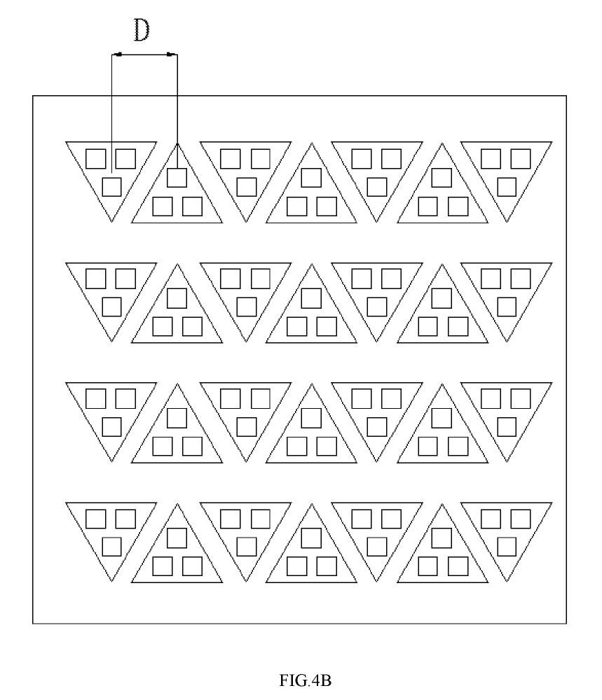

Individual LED devices are obtained after all LED units on the LED circuit board are cut along side boundaries. Refer to FIG. 3A and FIG. 3B, which are schematic views of an LED device of the present invention, wherein FIG. 3A is a front view, and FIG. 3B is a rear view. It should be noted that, after boring, the three corners of the LED device are unfilled because of the boring, but the unfilled corners are not shown in the figures. The structure of the LED device is consistent with that of the LED unit, including a substrate, pads, pins, LED chips 50, wire solders and encapsulating glue. The substrate is a panel in a regular triangle shape. The pads include three die bond pads 31 which are respectively disposed at the three vertexes of the substrate, and a common pad 32 which is positioned approximately at the middle portion of the substrate. The substrate is formed with a through-hole corresponding to each one of the pads, and conductive materials are disposed in the through-holes or on the inner walls of the through-holes, for example the inner walls of the through-holes are electroplated with copper, so all pads can electrically communicate with the back of the substrate through the through-holes. Four pins are disposed on the back of the substrate. The pins are metal pins, including three chip pins 41 and a common pin 42; the pins are mutually electrically insulated, and are disposed corresponding to the positions of the through-holes. In this way, each one of the pads can electrically communicate with each corresponding one of the pins. Each one of the LED devices is provided with three LED chips 50, and each one of the LED chips 50 is fixed on each corresponding one of the die bond pads 31. Preferably, the three LED chips include a red LED chip, a blue LED chip and a green LED chip. An electrode of the red LED chip is directly electrically connected with the die bond pads, and the other electrode is electrically connected with the common pad through the wire solder. The two electrodes of each one of the blue LED chip and the green LED chip are respectively connected with the die bond pads and the common pad through wire solders. The encapsulating glue uniformly covers the substrate to encapsulate the LED chips 50, the wire solders and the pads in a sealed way.

LED Display

### Embodiment 1

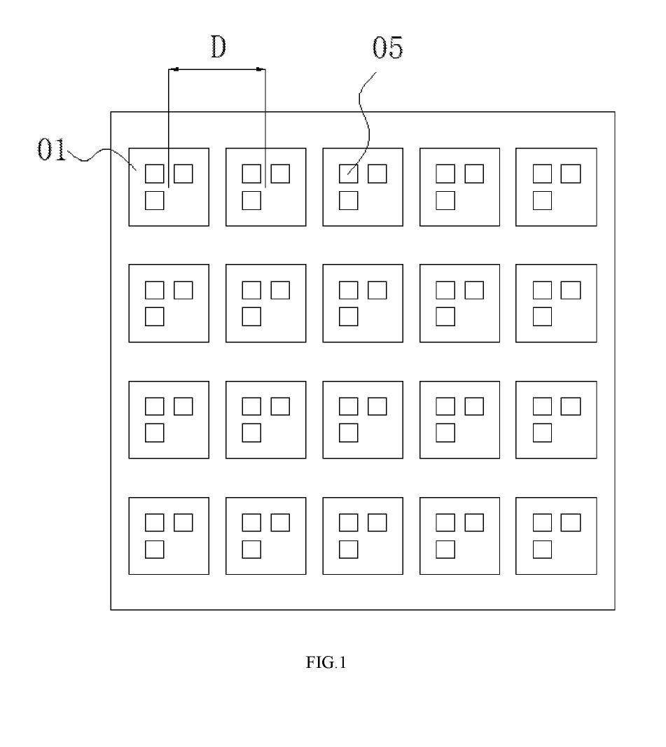

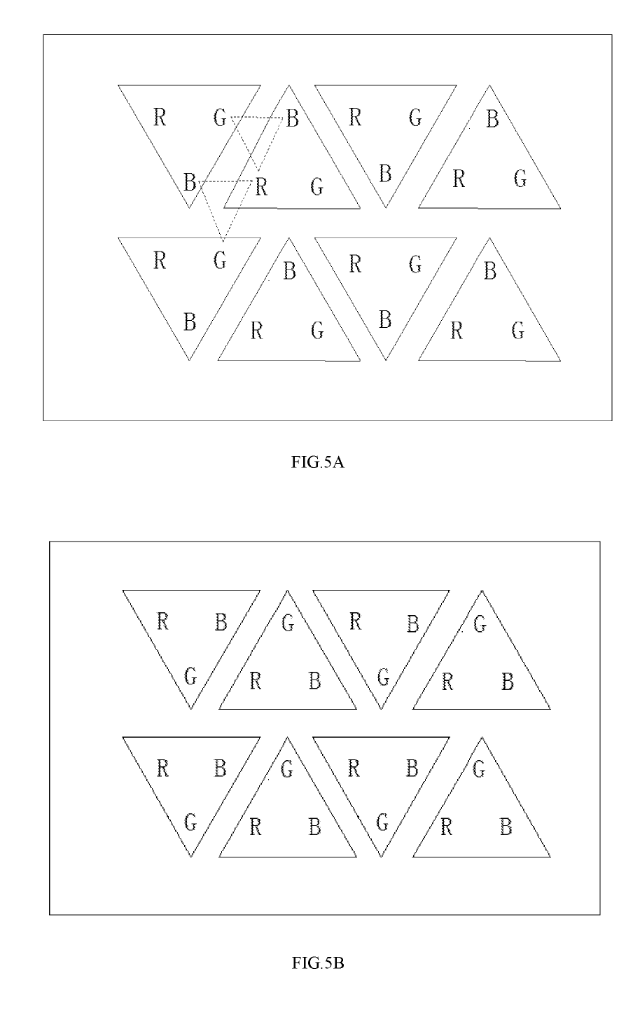

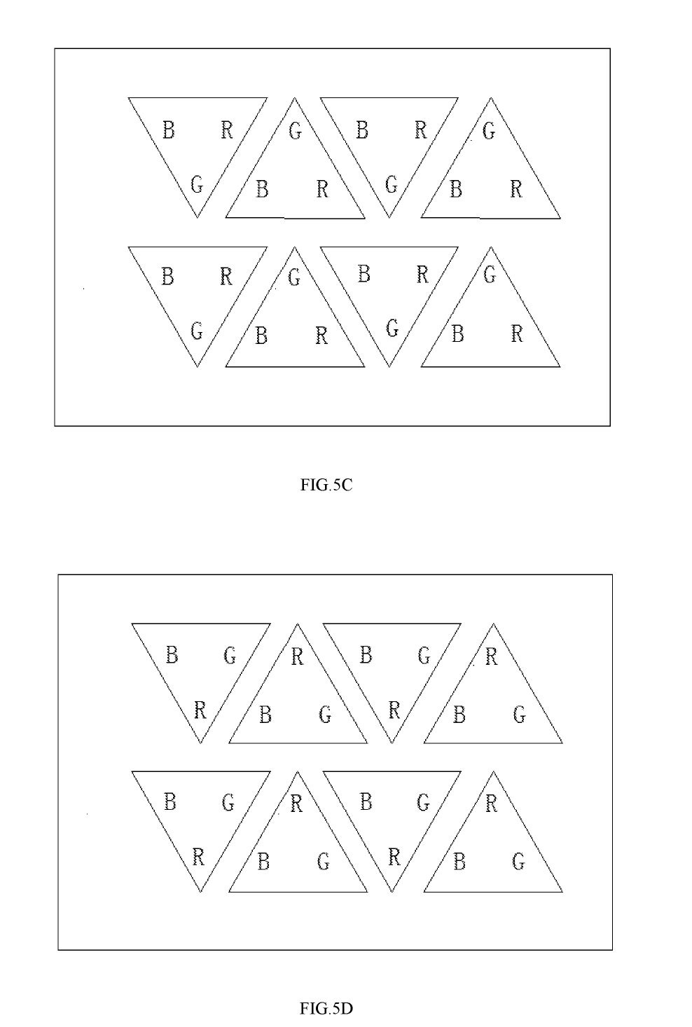

After the aforementioned plurality of triangular LED devices are arrayed at an equal interval, an LED display can be formed. Refer to FIG. 4A and FIG. 4B. FIG. 4A and FIG. 4B are schematic views of the LED display of the present invention, wherein FIG. 4A is a front view, and FIG. 4B is a schematic view of an LED display compared with the prior art in FIG. 1. The LED display includes LED devices, a PCB 60 and a drive IC. Rows of LED devices are arrayed on the PCB 60, and welded at corresponding positions on the PCB 60 through pins on the backs of the LED devices. The drive IC is installed on the back of the PCB 60. Through the circuits on the PCB 60 and the top-bottom run-through bored holes, the LED devices are electrically connected with the drive IC. The LED devices are controlled by using the drive IC, thus realizing display on the LED display.

The LED devices are arrayed in an up-down aligned way. All horizontally adjacent LED devices are arrayed upward and downward in an alternative way at an equal interval, wherein the upward arrangement refers to the bottom edge of a triangle being located at the bottom, and the downward arrangement refers to the bottom edge of the triangle being positioned on the top. All longitudinally adjacent LED devices are arrayed both upward or both downward. It should be noted that the “upward”, “downward”, “horizontally” and “longitudinally” as described in the description all refer to orientations or position relationships in the figures for the purpose of simplifying the description. Such orientations or position relationships are relative terms, and therefore cannot be regarded as limits in the present invention, for example if the angle of view is correspondingly shifted or overturned, the orientations or position relationships of the “upward” and “downward”, and the “horizontally” and “longitudinally” are exchanged. Refer to FIG. 4B, compared with the prior art as shown in FIG. 1, under the condition that the side lengths of the LED devices are identical, which means that the side lengths of the square LED devices are identical with the side lengths of the triangular LED devices, the volume of the triangular LED devices is smaller; moreover, in virtue of the above-mentioned upward-downward alternative array mode, the interval D between the LED devices is smaller than the interval as shown in FIG. 1, capable of effectively increasing the number of the LED devices under the condition that the area of the LED display is identical, thus improving the pixel definition of the display.

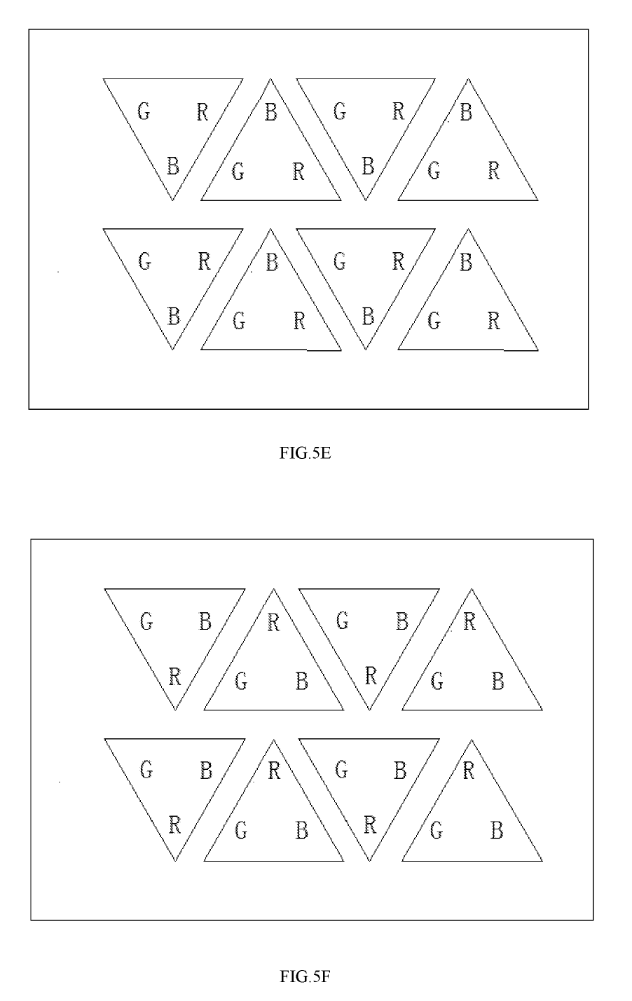

Further, the LED chips are RGB chips (the red LED chip, green LED chip, and blue LED chip are respectively called R, B chips in short), and every three adjacent LED chips form an RGB triangular dot matrix at the same time, achieving a light mixing effect. Refer to FIGS. 5A-F, which shows the array mode of the RGB triangular dot matrix of the LED display of the present invention. The specific array modes are varied, only six of which are listed here. FIGS. 5A-F show six different optional array modes. Taking FIG. 5A as an example, adjacent LED devices include LED devices which are placed upward and LED devices which are placed downward. The LED chips of LED devices which are placed downward are all arrayed in a way that R is positioned at the upper left, G positioned at the upper right, and B at the bottom; the LED chips of the LED devices which are placed upward are all arrayed in a way that B is positioned on the top, R positioned at the lower left, and G at the lower right. The purpose of such configuration is that any three adjacent LED chips in every two or three adjacent LED devices also form an RGB triangular dot matrix, like the dotted triangle as shown in FIG. 5A. In this way, the adjacent LED devices generate a light mixing effect, and the whole LED display presents surface light emission, so the emergent light of the display module is softer.

In FIGS. 5B-F, the array modes of the LED chips are different, but the principle is identical. Specifically, in FIG. 5B, the downward triangular dot matrix is arrayed in a way that R is positioned at the upper left, B positioned at the upper right, and G at the bottom; the upward triangular dot matrix is arrayed in a way that G is positioned on the top, R positioned at the lower left, and B at the lower right. In FIG. 5C, the downward triangular dot matrix is arrayed in a way that B is positioned at the upper left, R positioned at the upper right, and G at the bottom; the upward triangular dot matrix is arrayed in a way that G is positioned on the top, B positioned at the lower left, and R at the lower right. In FIG. 5D, the downward triangular dot matrix is arrayed in a way that B is positioned at the upper left, G positioned at the upper right, and R at the bottom; the upward triangular dot matrix is arrayed in a way that R is positioned on the top, B positioned at the lower left, and G at the lower right. In FIG. 5E, the downward triangular dot matrix is arrayed in a way that G is positioned at the upper left, R positioned at the upper right, and B at the bottom; the upward triangular dot matrix is arrayed in a way that B is positioned on the top, G positioned at the lower left, and R at the lower right. In FIG. 5F, the downward triangular dot matrix is arrayed in a way that G is positioned at the upper left, B positioned at the upper right, and R at the bottom; the upward triangular dot matrix is arrayed in a way that R is positioned on the top, G positioned at the lower left, and B at the lower right.

A manufacturing method of the LED display of the present invention includes the following steps of: manufacturing a substrate; installing pads on one side of the substrate and installing pins at the other side, wherein specifically, the pads can be installed by two approaches, one referring to direct electro-coppering in a designed area, and the other including procedures of forming a layer of copper on the substrate surface first and then etching away unnecessary parts; boring holes on the substrate; respectively fixing the LED chips on the die bond pads, respectively welding wire solders on the LED chips and the pads; pouring encapsulating glue on the substrate to cover the LED chips, wire solders and pads, then curing the glue; cutting the LED chips along side boundaries to form individual LED devices; welding the LED devices on the PCB through pins, and welding circuit components of the drive IC on the other side of the PCB. Thus, the manufacturing of the LED display is completed.

LED Display

### Embodiment 2

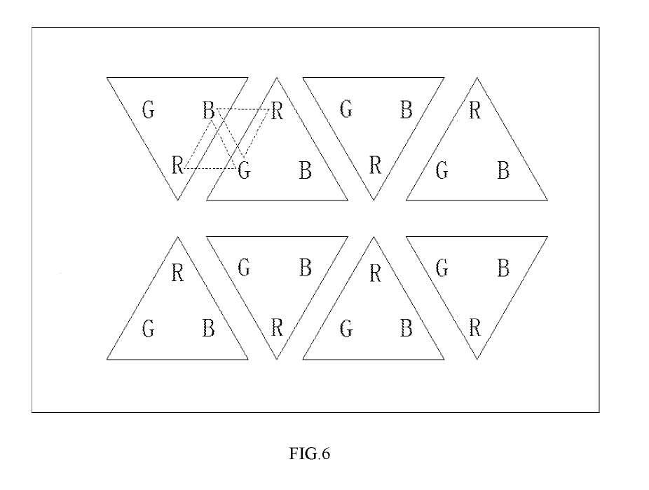

Refer to FIG. 6, which shows an RGB triangular dot matrix array mode of an LED display in embodiment 2 of the present invention. Embodiment 2 is basically the same as Embodiment 1, the only difference lies in the following configurations: horizontally adjacent LED devices are still arrayed upward and downward in an alternative way at an equal interval. The only difference lies in that longitudinally adjacent LED devices are also arrayed upward and downward in an alternative way at an equal interval. Every three adjacent LED chips form an RGB triangular dot matrix at the same time, realizing a light mixing effect. Specific array modes are varied. Here, only one array mode is taken as an example. The LED chips of LED devices which are placed downward are all arrayed in a way that G is positioned at the upper left, B positioned at the upper right, and R at the bottom; the LED chips of the LED devices which are placed upward are all arrayed in a way that R is positioned at the upper left, G positioned at the lower left, and B at the lower right.

In the present invention, triangular LED units are set to form triangular LED devices which can be more densely arrayed on a PCB, so an LED display with LED devices arrayed at a smaller distance is generated, and pixel definition is strengthened. Meanwhile, in an LED circuit board, the LED units are closely arranged in a hexagonal shape, so the utilization rate of materials can be enhanced; moreover, a plurality of LED units can be bored at one time at the central point of the hexagon, and finally the LED devices can be quickly obtained by simple cutting, thus effectively enhancing the processing efficiency and reducing production cost. Further, the LED chips are RGB chips, and the LED devices are arrayed on the LED display in a specific manner. In this way, adjacent LED devices can achieve a light mixing effect. The whole LED display presents surface light emission, so the emergent light of the display module is softer.

The present invention is not limited in the above embodiment. All modifications and changes of the present invention made on the basis of the spirit or scope of the present invention shall fall within the protective scope of the claims of the present invention.

What is claimed is:

1. A triangular-combination LED circuit board, comprising a plurality of triangular LED units, wherein vertexes of every six of the LED units are superimposed to jointly form a hexagonal central point such that every six of the LED units form a hexagonal LED array; the LED unit comprises a substrate and pads disposed on the substrate; the pads comprise die bond pads; and three die bond pads are provided, respectively disposed at three vertexes of the triangular LED units.

2. The triangular-combination LED circuit board of claim 1, wherein the LED unit is regular-triangle-shaped.

3. The triangular-combination LED circuit board of claim 1, wherein the pads further comprise a common pad; the substrate is formed with a plurality of through-holes; the through-holes are respectively disposed at triangular vertexes of the LED units and on the common pad; pins are disposed on back of the substrate, and the pins are disposed corresponding to the through-holes.

4. The triangular-combination LED circuit board of claim 1, further comprising LED chips, wire solders and encapsulating glue; the LED chips are respectively fixed on the die bond pads; the wire solders respectively electrically connect the LED chips and the pads; and the encapsulating glue covers the substrate to encapsulate the LED chips and the wire solders.

5. A triangular LED device, obtained by cutting the triangular-combination LED circuit board of claim 1, comprising a substrate, pads and LED chips; the substrate is triangular-shaped; the pads comprise three die bond pads which are respectively disposed at three vertexes of the substrate, and the LED chips are respectively fixed on the die bond pads.

6. The triangular LED device of claim 5, further comprising wire solders and encapsulating glue; the wire solders respectively electrically connect the LED chips and the pads; and the encapsulating glue covers the substrate to encapsulate the LED chips and the wire solders.

7. The triangular LED device of claim 6, wherein the pads further comprise a common pad; the substrate is formed with a plurality of through-holes; the through-holes are respectively disposed at three vertexes of the substrate and on the common pad; pins are disposed on back of the substrate, and the pins are disposed corresponding to the through-holes.

8. The triangular LED device of claim 6, wherein the LED chips comprise a red LED chip, a blue LED chip and a green LED chip.

9. An LED display, comprising a plurality of LED devices; horizontally adjacent LED devices are arrayed upward and downward in an alternative way at an equal interval, and the LED devices are triangular LED devices of claim 5.

10. The LED display of claim 9, further comprising wire solders and encapsulating glue; the wire solders respectively electrically connect the LED chips and the pads; and the encapsulating glue covers the substrate to encapsulate the LED chips and the wire solders.

11. The LED display of claim 10, wherein the pads further comprise a common pad; the substrate is formed with a plurality of through-holes; the through-holes are respectively disposed at three vertexes of the substrate and on the common pad; pins are disposed on back of the substrate, and the pins are disposed corresponding to the through-holes.

12. The LED display of claim 10, wherein the LED chips comprise a red LED chip, a blue LED chip and a green LED chip.

13. The LED display of claim 9, wherein each one of the LED devices comprises three LED chips, namely a red LED chip, a green LED chip and a blue LED chip; and the LED chips of every two or three adjacent LED devices can form an RGB triangular dot matrix which comprises a red LED chip, a blue LED chip and a green LED chip.

14. The LED display of claim 10, wherein each one of the LED devices comprises three LED chips, namely a red LED chip, a green LED chip and a blue LED chip; and the LED chips of every two or three adjacent LED devices can form an RGB triangular dot matrix which comprises a red LED chip, a blue LED chip and a green LED chip.

15. The LED display of claim 11, wherein each one of the LED devices comprises three LED chips, namely a red LED chip, a green LED chip and a blue LED chip; and the LED chips of every two or three adjacent LED devices can form an RGB triangular dot matrix which comprises a red LED chip, a blue LED chip and a green LED chip.

16. The LED display of claim 12, wherein each one of the LED devices comprises three LED chips, namely a red LED chip, a green LED chip and a blue LED chip; and the LED chips of every two or three adjacent LED devices can form an RGB triangular dot matrix which comprises a red LED chip, a blue LED chip and a green LED chip.
